(19) United States
(12) Patent Application Publication
(10) Pub. No.: US 2023/0403939 A1
(43) Pub. Date: Dec. 14, 2023

(54) PACKAGED ACOUSTIC WAVE DEVICES WITH MULTILAYER PIEZOELECTRIC SUBSTRATE

(71) Applicant: Skyworks Solutions, Inc., Irvine, CA (US)

(72) Inventors: Rei Goto, Osaka-Shi (JP); Hironori Fukuhara, Ibaraki-Shi (JP)

(21) Appl. No.: 18/208,800

(22) Filed: Jun. 12, 2023

Related U.S. Application Data
(60) Provisional application No. 63/351,698, filed on Jun. 13, 2022.

(51) Int. Cl. H10N 30/88; H03H 3/08; H03H 3/04; H03H 9/02

(52) U.S. Cl. CPC H10N 30/88; H03H 3/08; H03H 3/04; H03H 9/02574

(57) ABSTRACT

A packaged acoustic wave component can include a dielectric layer disposed over a substrate, a piezoelectric structure disposed over the dielectric layer, and an electrode structure disposed over the piezoelectric structure. The component can further include a polymer structure including a polymer structure wall portion and a polymer structure roof portion configured to form a cavity over the electrode structure, a metal structure disposed over the polymer structure. A buffer coating can be disposed over the metal structure. The buffer coating can include a polymer material with a filler material.

### CROSS REFERENCE TO RELATED APPLICATION

This application incorporates by reference in its entirety for all purposes U.S. Provisional Application No. 63/351,698, filed on Jun. 13, 2022. Any and all applications for which a foreign or domestic priority claim is identified in the Application Data Sheet of the present application are hereby incorporated by reference in their entireties under 37 CFR 1.57.

### BACKGROUND

### Technical Field

Embodiments of this disclosure relate to acoustic wave devices, in particular to packaged acoustic wave components, which may also be designated as acoustic wave component packages.

### Description of Related Technology

Acoustic wave filters can be implemented in radio frequency electronic systems. For instance, filters in a radio frequency front end of a mobile phone can include acoustic wave filters. An acoustic wave filter can filter a radio frequency signal. An acoustic wave filter can be a band pass filter. A plurality of acoustic wave filters can be arranged as a multiplexer. For example, two acoustic wave filters can be arranged as a duplexer.

An acoustic wave filter can include a plurality of resonators arranged to filter a radio frequency signal. Example acoustic wave filters include surface acoustic wave (SAW) filters and bulk acoustic wave (BAW) filters. A surface acoustic wave resonator can include an interdigital transductor electrode on a piezoelectric substrate. The surface acoustic wave resonator can generate a surface acoustic wave on a surface of the piezoelectric layer on which the interdigital transductor electrode is disposed.

The packaging process for multilayer piezoelectric substrate packages with an acoustic wave device, so as to produce a packaged acoustic wave component, can apply stresses to the piezoelectric layer (e.g., during heat cycle testing) that can result in reliability issues including cracking of the piezoelectric layer.

### SUMMARY

Accordingly, there is a need for a packaged acoustic wave component, in particular a surface acoustic wave (e.g., SAW or TCSAW) package with improved reliability that can withstand the stresses (e.g., from heat cycle testing) during the packaging process.

In accordance with one aspect of the disclosure, a packaged acoustic wave component comprises: a substrate; a dielectric layer disposed over the substrate; a piezoelectric structure disposed over the dielectric layer; an electrode structure disposed over the piezoelectric structure; a polymer structure comprising a polymer structure wall portion and a polymer structure roof portion configured to form a cavity over the electrode structure; a metal structure disposed over the polymer structure; and a buffer coating disposed over the metal structure, the buffer coating comprising or consisting of a polymer material with a filler material.

In accordance with one aspect of the disclosure, a method of making a packaged acoustic wave component comprises the steps of: forming an acoustic wave device including forming or providing a substrate, forming or providing a piezoelectric structure over at least a portion of the substrate and forming or providing an electrode structure disposed over the piezoelectric structure; forming or providing a metal structure disposed over the polymer structure; and forming a buffer coating disposed over the metal structure, the buffer coating comprising of consisting of a polymer material with a filler material.

In some aspects, the techniques described herein relate to a packaged acoustic wave component including: a substrate; a dielectric layer disposed over the substrate; a piezoelectric structure disposed over the dielectric layer; an electrode structure disposed over the piezoelectric structure; a polymer structure including a polymer structure wall portion and a polymer structure roof portion configured to form a cavity over the electrode structure; a metal structure disposed over the polymer structure; and a buffer coating disposed over the metal structure, the buffer coating including a polymer material with a filler material.

In some aspects, the techniques described herein relate to a packaged acoustic wave component wherein the filler material includes or consists of a silica-based filler material.

In some aspects, the techniques described herein relate to a packaged acoustic wave component wherein the silica-based filler material includes or consists of silicon dioxide and/or silicon nitride.

In some aspects, the techniques described herein relate to a packaged acoustic wave component wherein the filler material includes or consists of one or more of: aluminium oxide, magnesium oxide, borium nitride, and aluminium nitride.

In some aspects, the techniques described herein relate to a packaged acoustic wave component wherein the polymer material of the buffer coating includes or consists of a polyimide material and/or a polybenzoxazole material.

In some aspects, the techniques described herein relate to a packaged acoustic wave component wherein the buffer coating has a Young's modulus E of 5 gigapascals or more.

In some aspects, the techniques described herein relate to a packaged acoustic wave component wherein the buffer coating has a coefficient of thermal expansion of 20 ppm or less.

In some aspects, the techniques described herein relate to a packaged acoustic wave component wherein the buffer coating has a coefficient of thermal expansion of 16.5 ppm or less.

In some aspects, the techniques described herein relate to a packaged acoustic wave component wherein the polymer structure includes a polymer material, which includes, or consists of, a polyimide material and/or a polybenzoxazole material.

In some aspects, the techniques described herein relate to a packaged acoustic wave component wherein the polymer structure further includes a filler material.

In some aspects, the techniques described herein relate to a packaged acoustic wave component wherein the filler material of the polymer structure includes or consists of a silica-based filler material.

In some aspects, the techniques described herein relate to a packaged acoustic wave component wherein the silica-based filler material of the polymer structure includes or consists of silicon dioxide and/or silicon nitride.

In some aspects, the techniques described herein relate to a packaged acoustic wave component wherein the filler material of the polymer structure includes or consists of one or more of: aluminium oxide, magnesium oxide, borium nitride, and aluminium nitride.

In some aspects, the techniques described herein relate to a packaged acoustic wave component wherein the polymer structure has a Young's modulus E of 5 gigapascals or more.

In some aspects, the techniques described herein relate to a packaged acoustic wave component wherein the polymer structure has a coefficient of thermal expansion of 20 ppm or less.

In some aspects, the techniques described herein relate to a packaged acoustic wave component wherein the buffer coating has a coefficient of thermal expansion of 16.5 ppm or less.

In some aspects, the techniques described herein relate to a packaged acoustic wave component wherein the substrate, the dielectric layer and the piezoelectric structure have a common outer lateral edge.

In some aspects, the techniques described herein relate to a packaged acoustic wave component wherein a gap is arranged between the piezoelectric structure and the polymer structure.

In some aspects, the techniques described herein relate to a packaged acoustic wave component wherein the gap is also arranged between the dielectric layer and the polymer structure.

In some aspects, the techniques described herein relate to a packaged acoustic wave component wherein in the gap the substrate is open to the cavity.

In some aspects, the techniques described herein relate to a packaged acoustic wave component wherein the electrode structure includes at least one interdigital transducer electrode.

In some aspects, the techniques described herein relate to a wireless communication device including: a packaged radio frequency device including an acoustic wave component formed from a dielectric layer disposed over a substrate, a piezoelectric structure disposed over the dielectric layer, an electrode structure disposed over the piezoelectric structure, a polymer structure including a polymer structure wall portion and a polymer structure roof portion configured to form a cavity over the electrode structure, a metal structure disposed over the polymer structure, and a buffer coating disposed over the metal structure, the buffer coating including a polymer material with a filler material; and an antenna coupled to the packaged radio frequency device.

In some aspects, the techniques described herein relate to a wireless communication device wherein the packaged radio frequency device is a radio frequency front end including the acoustic wave component and a power amplifier.

In some aspects, the techniques described herein relate to a method of making a packaged acoustic wave component, the method including: forming an acoustic wave device including forming or providing a substrate, forming or providing a piezoelectric structure over at least a portion of the substrate and forming or providing an electrode structure disposed over the piezoelectric structure; forming or providing a polymer structure including a polymer structure wall portion and a polymer structure roof portion configured to form a cavity over the electrode structure; and forming or providing a metal structure disposed over the polymer structure; and forming a buffer coating disposed over the metal structure, the buffer coating including a polymer material with a filler material.

### BRIEF DESCRIPTION OF THE DRAWINGS

Embodiments of this disclosure will now be described, by way of non-limiting example, with reference to the accompanying drawings.

FIG. 1 illustrates a schematic cross-sectional side view of a packaged acoustic wave component according to an embodiment.

FIG. 2 illustrates a schematic cross-sectional side view of another packaged acoustic wave component.

FIG. 3A illustrates a detail of a schematic cross-sectional side view of a conventional packaged acoustic wave component.

FIG. 3B illustrates a graphical result of a stress simulation of the parts shown in FIG. 3A.

FIG. 3C illustrates numerical results of a stress simulation in the piezoelectric layer of the conventional packaged acoustic wave component of FIG. 3A.

FIG. 4A illustrates a detail of a schematic cross-sectional side view of the packaged acoustic wave component according to the embodiment of FIG. 1.

FIG. 4B illustrates a graphical result of a stress simulation of the parts shown in FIG. 4A.

FIG. 4C illustrates numerical results of a stress simulation in the piezoelectric layer of the packaged acoustic wave component of FIGS. 1 and 4A.

FIG. 5A illustrates a detail of a schematic cross-sectional side view of a packaged acoustic wave component according to a variant of the embodiment of FIG. 1.

FIG. 5B illustrates a graphical result of a stress simulation of the parts shown in FIG. 5A.

FIG. 5C illustrates numerical results of a stress simulation in the piezoelectric layer of the packaged acoustic wave component variant of FIG. 5A.

FIG. 6 illustrates a method of making the Multi-layer piezoelectric substrate (MPS) package structure of FIGS. 1-2 and 4A-5A.

FIG. 7A is a schematic diagram of a transmit filter that includes a surface acoustic wave resonator according to an embodiment.

FIG. 7B is a schematic diagram of a receive filter that includes a surface acoustic wave resonator according to an embodiment.

FIG. 8 is a schematic diagram of a radio frequency module that includes a surface acoustic wave resonator according to an embodiment.

FIG. 9 is a schematic diagram of a radio frequency module that includes filters with surface acoustic wave resonators according to an embodiment.

FIG. 10 is a schematic block diagram of a module that includes an antenna switch and duplexers that include a surface acoustic wave resonator according to an embodiment.

FIG. 11A is a schematic block diagram of a module that includes a power amplifier, a radio frequency switch, and duplexers that include a surface acoustic wave resonator according to an embodiment.

FIG. 11B is a schematic block diagram of a module that includes filters, a radio frequency switch, and a low noise amplifier according to an embodiment.

FIG. 12A is a schematic block diagram of a wireless communication device that includes a filter with a surface acoustic wave resonator in accordance with one or more embodiments.

FIG. 12B is a schematic block diagram of another wireless communication device that includes a filter with a surface acoustic wave resonator in accordance with one or more embodiments.

### DETAILED DESCRIPTION

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings.

Acoustic wave filters can filter radio frequency (RF) signals in a variety of applications, such as in an RF front end of a mobile phone. An acoustic wave filter can be implemented with surface acoustic wave (SAW) devices. SAW devices include SAW resonators, SAW delay lines, and multi-mode SAW (MMS) filters (e.g., double mode SAW (DMS) filters). Any features of the SAW resonators and/or devices discussed herein can be implemented in any suitable SAW device.

In general, high quality factor (Q), large effective electromechanical coupling coefficient (k2), high frequency ability, and spurious free response can be significant aspects for acoustic wave elements to enable low-loss filters, delay lines, stable oscillators, and sensitive sensors.

Multi-layer piezoelectric substrate (MPS) SAW resonators can thermally insulate an interdigital transducer electrode and a piezoelectric layer. By reducing dissipative thermal impedance of the SAW device, the ruggedness and power handling can be improved.

Some MPS SAW resonators have achieved high Q by confining energy and good thermal dissipation using a silicon (Si) support layer. However, such approaches have encountered technical challenges related to undesirable higher frequency spurious responses.

Some other MPS SAW resonators have achieved high Q by confining energy and have also reduced higher frequency spurious responses. However, such approaches have encountered relatively low thermal heat dissipation.

Aspects of the present disclosure relate to SAW resonators that include a support substrate or layer (e.g., a single crystal supporting substrate), a functional layer (e.g., a dielectric layer) over the support substrate or layer, a piezoelectric layer (e.g., a lithium niobate (LN or LiNbO3) layer or a lithium tantalate (LT or LiTaO3) layer) over the functional layer, and an interdigital transducer (IDT) electrode over the piezoelectric layer. Such SAW resonators can also include a temperature compensation layer (e.g., silicon dioxide (SiO2) layer) over the IDT electrode in certain embodiments. The SAW resonators can also include an adhesion layer disposed between the support substrate and the functional layer and/or an adhesion layer between the functional layer and the piezoelectric layer, in certain applications.

SAW resonators with the functional layer and the support layer or substrate can beneficially provide a relatively high effective electromechanical coupling coefficient (k2), a relatively high quality factor (Q), a relatively high power durability and thermal dissipation, and reduced high frequency spurious responses. The high coupling coefficient (k2) can be beneficial for relatively wide bandwidth filters. The high quality factor (Q) can beneficially lead to a relatively low insertion loss. The reduced high frequency spurious may make the SAW resonators compatible with multiplexing with higher frequency bands.

In an embodiment, an MPS SAW resonator includes a piezoelectric layer over a functional layer over a silicon support substrate or layer. The silicon support substrate can reduce thermal impedance of the MPS SAW resonator. The functional layer can be a single crystal layer arranged to confine acoustic energy and lower a higher frequency spurious response. The piezoelectric layer, the functional layer, and the silicon support substrate can all be single crystal layers.

Embodiments of MPS SAW resonators (e.g., packages) will now be discussed. Any suitable principles and advantages of these MPS SAW resonators can be implemented together with each other in an MPS SAW resonator and/or in an acoustic wave filter. MPS SAW resonators (e.g., packages) disclosed herein can have lower loss than certain bulk acoustic wave devices.

FIG. 1 illustrates a packaged acoustic wave component 100 (e.g., a multi-layer piezoelectric substrate (MPS) package or structure) according to an embodiment. The component 100 has a substrate 116, an additional (e.g., functional, dielectric) structure or layer 114 disposed over (e.g., bonded to) the substrate 116, and a piezoelectric structure or layer 112 disposed over (e.g. bonded to) the functional layer 114. The functional layer 114 may comprise, for example, silicon ducts to improve thermal properties and/or the temperature coefficient of frequency (TCF). An electrode structure, specifically an interdigital transducer (IDT) electrode 110, is disposed on (e.g., connected to) the piezoelectric layer 112 as part of a first metal layer. The dielectric layer 114 can also be designated as a functional layer as it may provide one or more functions. On the first metal layer, a second metal layer M2 can be provided which usually has a higher thickness than the first metal layer, in order to reduce its electrical resistivity. The second metal layer M2 may be used to form signal lines connecting the IDT electrode 110 to contact terminals of the packaged acoustic wave component 100, e.g. to solder connections 104.

With continued reference to FIG. 1, a thermally conductive structure or package 102 is connected to the substrate 116 via at least piezoelectric layer 112 and functional (specifically, dielectric) layer 114. The thermally conductive structure or package 102 includes a metal structure 108 and a polymer structure 109 disposed over at least a portion of the metal structure 108. The polymer structure 109 may in particular comprise, or consist of, a polyimide material and/or a polybenzoxazole (PBO) material.

The metal structure 108 and the polymer structure 109 are shaped so that a cavity C (e.g., open or hollow cavity, air cavity) exists between at least a portion of the polymer structure 109 and at least a portion of the piezoelectric layer 112. The cavity C houses (or: encloses) the IDT 110 and may house (or: enclose) the functional layer 114 and/or the piezoelectric layer 112 partially or completely. The polymer structure 109 may thus comprise a polymer structure wall portion 109A (forming the walls of the cavity C) and a polymer structure roof portion 109B (forming the roof of the cavity C). The metal structure 108 can be made of copper (Cu). The metal structure 108 may comprise a metal structure wall portion 108A and a metal structure roof portion 108B arranged in contact with the polymer structure wall portion 109A and the polymer structure roof portion 109B, respectively.

A buffer coating (or: dielectric overcoat) 106) is disposed over at least a portion of the metal structure 108. The buffer coating 106 may comprise any suitable polymer which may be chosen such as to provide a desired hardness. One or more solder connections 104 are disposed on the metal structure 108 so that the metal structure 108 is between the solder connections 104 and the piezoelectric layer 112. The metal structure 108 connects to the piezoelectric layer 112 via—not depicted—signal line(s) (e.g., so at least a portion of the piezoelectric layer 112 and dielectric layer 114 are disposed between the signal line(s) and the substrate 116).

In the shown cross-section, two solder connections 104 (or: solder terminal external electrodes) are directly electrically connected via the metal structure 108. This may be done for ground, GND, solder connections 104 (or: GND terminals) to enforce GND stability. Typically, another, electrically separate solder connection 104 (not shown in FIG. 1) will be provided as a signal electrode, in the same layer(s) but without direct electrical connection to the GND solder connections 104 within the metal structure 108.

During the packaging process, the piezoelectric layer 112 and/or the dielectric layer 114 can be subjected to high stresses, for example due to the different thermal expansion performances of the substrate 116 and the thermally conductive structure or package 102 (e.g., during a heat cycle test), which are transferred to the piezoelectric layer 112 by the metal structure 108 via the signal line(s). Such high stresses can result in damage (e.g., deformation, cracks) to the piezoelectric layer 112 and/or dielectric layer 114.

The inventors have found that said stress issues can be improved by providing the buffer coating 106 as comprising a polymer material with (or: including) a filler material. The filler material may comprise or consist of a silica-based filler material such as silicon dioxide, SiO2 or silicon nitride, Si3N4. The filler material may also comprise or consist of aluminium oxide, Al2O3, magnesium oxide, MgO, borium nitride, BN, aluminium nitride, AlN, and/or the like. The polymer material of the buffer coating 106 comprises or consists of a polyimide material and/or a polybenzoxazole (PBO) material.

It has also been found to be advantageous by the inventors when the buffer coating 106 has a Young's modulus E of 5 gigapascals or more, and/or when the buffer coating 106 has a coefficient of thermal expansion, CTE, of 20 ppm or les, preferably of 16.5 ppm or less.

Furthermore, it has been found to be advantageous when also the polymer structure 109 comprises a filler material. The filler material may comprise or consist of a silica-based filler material such as silicon dioxide. The polymer structure 109 advantageously has a Young's modulus E of 5 gigapascals or more, and/or a coefficient of thermal expansion, CTE, of 20 ppm or les, preferably of 16.5 ppm or less. Thus, in some variants, both polymer structure 109 and buffer coating 106 comprise a polymer filler, for example the same filler material, and they may even consist entirely of the same material. In other variants, only the polymer structure 109 or only the buffer coating 106 may comprise a filler material such as a silica-based filer material, e.g., silicon dioxide.

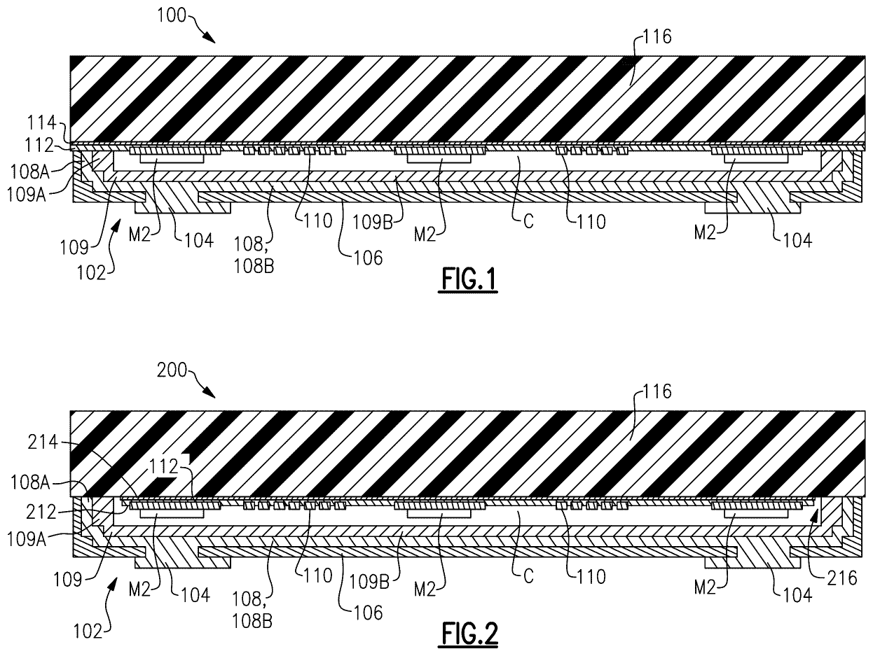

FIG. 2 shows a packaged acoustic wave component 200 (e.g., a multi-layer piezoelectric substrate (MPS) package or structure) according to another embodiment. The packaged acoustic wave component 200 is a variant of the packaged acoustic wave component 100 and differs from it in that a piezoelectric layer 212 is provided instead of the piezoelectric layer 112, and that a functional layer 214 is provided instead of the functional layer 114, wherein the differences are in form and size only, not (or not necessarily) in material. In this embodiment, the piezoelectric layer 212 (and optionally also the functional layer 214) is/are recessed with respect to the edge of the substrate 116. Thus, a gap 216 is present between the piezoelectric layer 212 and the functional layer 214 on one side, and the polymer structure 109 (specifically: the polymer structure wall portion 109A) on the other side. In this gap 216, the substrate 116 may be directly exposed to the cavity C. The gap 216 may be a gap zone surrounding the piezoelectric layer 212 and the functional layer 214 completely in two dimensions on the surface of the substrate 116. The polymer structure 109 in this embodiment therefore does not come into contact with either the piezoelectric layer 212 or the functional layer 214. This further reduces the stress on the piezoelectric layer 212 in particular during the packaging.

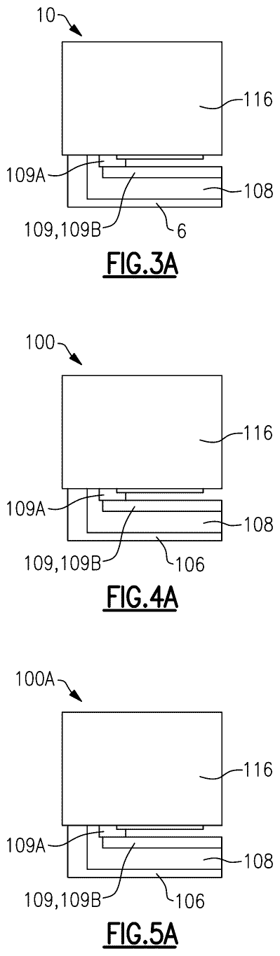

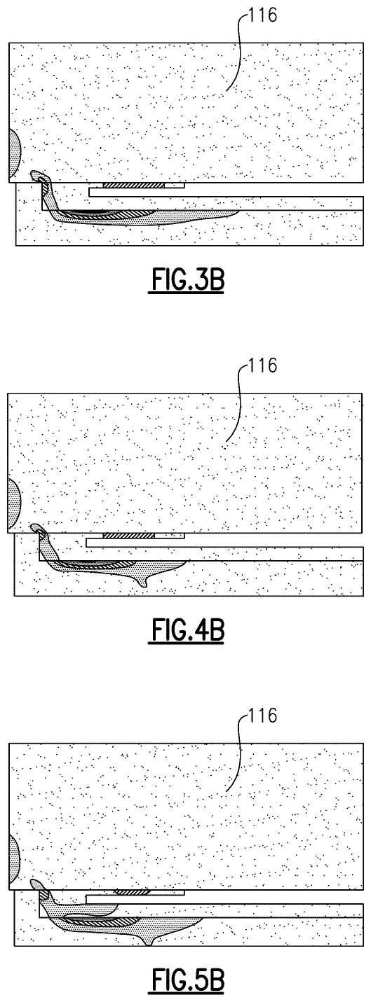

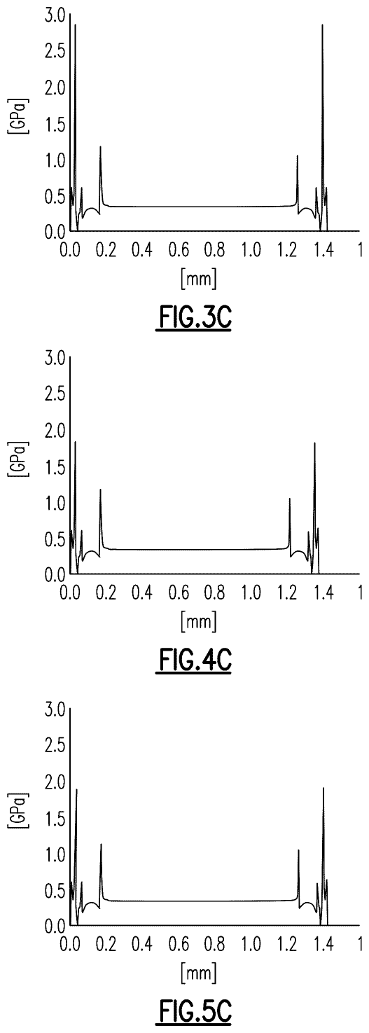

FIG. 3A illustrates a detail of a schematic cross-sectional side view of a conventional packaged acoustic wave component 10. In such a conventional packaged acoustic wave component 10, the buffer coating 6 does not comprise any filler material, in particular no silica-based filler material.

FIG. 3B illustrates a graphical result of a stress simulation of the parts shown in FIG. 3A. The large mechanical stress within the fragile piezoelectric layer 112 at the contact point between the metal structure 108, the buffer coating 6, and the substrate 116 is clearly visible.

FIG. 3C illustrates numerical results of a stress simulation in the piezoelectric layer 112 of the conventional packaged acoustic wave component 10 from one end (shown left in FIG. 3A) of a cross-section to the other (not shown). The large spikes of stress within the piezoelectric layer 112 are clearly visible. The peaks have determined to be at a stress value of 2.88 GPa (gigapascal) in the simulation.

FIG. 4A illustrates a detail of a schematic cross-sectional side view of the packaged acoustic wave component 100 according to an embodiment, wherein the buffer coating 106 comprises silicon dioxide as a filler material as has been described with respect to FIG. 1, for example.

FIG. 4B illustrates a graphical result of a stress simulation in the piezoelectric layer 112 of the parts shown in FIG. 4A. It is clearly visible that now the stress within the piezoelectric layer 112 at the contact point between the metal structure 108, the buffer coating 106, and the substrate 116 is greatly reduced.

FIG. 4C illustrates numerical results of a stress simulation in the piezoelectric layer 112 of the packaged acoustic wave component 100 of FIG. 1 and FIG. 4A from one end (shown left in FIG. 1 and FIG. 4A) to the other end (shown right in FIG. 1). With the vertical axis of FIG. 4C having the same scale as the one in FIG. 3C, the large reduction of the mechanical stress in the piezoelectric layer 112 of the packaged acoustic wave component 100 due to the filler material in the buffer coating 106 is evident. The peaks have determined to be at a stress value of 1.87 GPa (gigapascal) in the simulation.

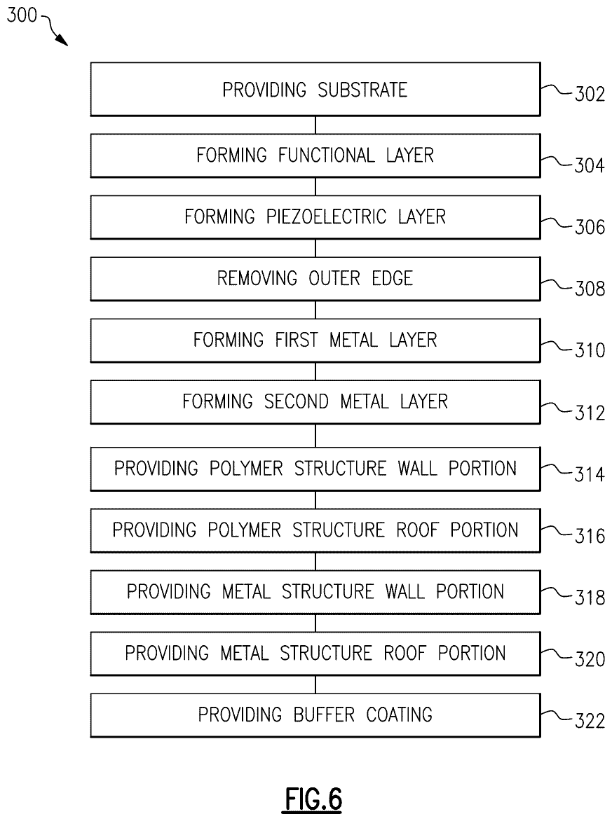

FIG. 5A illustrates a detail of a schematic cross-sectional side view of a packaged acoustic wave component 100A according to an embodiment. The packaged acoustic wave component 100A is a variant of the packaged acoustic wave component 100 and has already been described in the foregoing: the packaged acoustic wave component 100A differs from the packaged acoustic wave component 100 in that in the packaged acoustic wave component 100A also the polymer structure 109 comprises a filler material. For FIGS. 5A-5C, again silicon dioxide has been used as a filler material within a polyimide polymer material for the polymer structure 109. In addition, also the buffer coating 106 comprises silicon dioxide as a filler material as has been described with respect to FIG. 1, for example.

FIG. 5B illustrates a graphical result of a stress simulation in the piezoelectric layer 112 of the parts shown in FIG. 5A. It is clearly visible that the stress within the in the piezoelectric layer 112 at the contact point between the metal structure 108, the buffer coating 106, and the substrate 116 is also reduced when compared to FIG. 3B. Moreover, also the stress in the metal structure 108 (here essentially a copper plate) is advantageously reduced.

FIG. 5C illustrates numerical results of a stress simulation in the piezoelectric layer 112 of the packaged acoustic wave component 100A of FIG. 5A from one end (shown left FIG. 5A) to the other end (not shown). With the vertical axis of FIG. 5C having the same scale as the ones in FIG. 3C and FIG. 4C, the large reduction of the mechanical stress in the piezoelectric layer 112 of the packaged acoustic wave component 100A due to the filler material in both the buffer coating 106 and the polymer structure 109 is evident. The peaks have determined to be at a stress value of 1.89 GPa (gigapascal) in the simulation.

FIG. 6 illustrates a method 300 of making a packaged acoustic wave component (e.g., a multi-layer piezoelectric substrate (MPS) package or structure), such as the component 100, 100A or 200 in FIGS. 1, 2 and 4A, 5A. The method 300 includes the step 302 of forming or providing a substrate (e.g., substrate 116). The method 300 includes the step 304 of forming or providing a functional (e.g., temperature compensation, dielectric) structure or layer (such as the functional layer 114) over the substrate. The method 300 includes the step 306 of forming or providing a piezoelectric structure or layer (such as the piezoelectric layer 112) over the functional layer. The method 300 may include an optional step 308 of removing (e.g., etching) an outer edge or boundary of the piezoelectric layer 112 and functional layer 114, for example for making the packaged acoustic wave component 200 of FIG. 2. The method 300 includes a step 310 of forming the first metal layer including the IDT electrode 110, and a step 312 of forming the second metal layer M2. In further steps, the remainder of the thermally conductive structure 102 in any of the described variants may be provided and attached to the intermediate product comprising the substrate 116. The remainder of the thermally conductive structure 102 may be manufactured as a whole and then attached. Specifically, the thermally conductive structure 102 comprises the buffer coating 106 comprising or consisting of a polymer material (such as a polyimide) and a filler material (such as a silica-based filler, e.g., silicon dioxide). The same may also apply to the polymer structure 109 as has been described in the foregoing.

Alternatively, the following steps may be performed: In a step 314, the polymer structure wall portion 109A is provided (in particular: formed). In a step 316, the polymer structure roof portion 109B is provided (in particular: formed) over the polymer structure wall portion 109A in order to form the cavity C. The material for the polymer structure wall portion 109A and/or the polymer structure roof portion 109B may comprise or consist of a polymer material in combination with a filler material, e.g. a polyimide with a silicon dioxide filler. In a step 318, a metal structure wall portion 108A is provided (in particular: formed) such as to cover the polymer structure wall portion 109A and to contact the second metal layer M2 in two or more locations where the second metal layer M2 tunnels through the polymer structure wall portion 109A. In this way, an electrically conductive connection is provided between the IDT electrodes 110 and the metal structure 108. In a further step 320, the remainder of the metal structure 108, in particular the metal structure roof portion 108B of the metal structure 108, is provided. Steps 318 and 320 could also be performed at the same time. In a further step 322, the buffer coating 106 comprising the polymer material and the filler material, e.g. a polyimide with a silicon dioxide filler, is provided.

Since, as shown in FIG. 1, the polymer structure 109 is the only part of the thermally conductive structure 102 that contacts the portion of the packaged acoustic wave component 100 comprising the substrate 116, it is also possible that the metal structure 108 and/or the buffer coating 106 are formed on the polymer structure 109 after the thermally conductive structure 102 consisting of, or comprising, the polymer structure 109 has been attached. The buffer coating can be selectively formed, for example, by a photolithography method or a laser method.

In one implementation, a method of making a radio frequency module includes the steps above for method 300 in addition to forming or providing a package substrate and attaching additional circuitry and the packaged acoustic wave component to the package substrate.

Advantageously, the packaged acoustic wave component 100, 100A, 200 reduces the mechanical stress to which the piezoelectric and/or dielectric layers are subjected (e.g., during heat cycle testing due to the different thermal expansion characteristics of the substrate and the metal structure attached to the substrate) and avoid cracks or breaks therein. This results in improved reliability and mechanical ruggedness of the packaged acoustic wave components 100, 100A, 200. Such temperature performance advantageously allows use of the packaged acoustic wave components 100, 100A, 200 for high power applications (e.g., in a high power transmit filter). It also allows for a size reduction in the packaged acoustic wave component 100, 100A, 200, as described above.

An MPS acoustic wave resonator or device or die in a packaged acoustic wave component, including any suitable combination of features disclosed herein, can be included in a filter arranged to filter a radio frequency signal in a fifth generation (5G) New Radio (NR) operating band within Frequency Range 1 (FR1). A filter arranged to filter a radio frequency signal in a 5G NR operating band can include one or more MPS acoustic wave resonators disclosed herein. FR1 can be from 410 MHz to 7.125 GHz, for example, as specified in a current 5G NR specification. In 5G applications, the thermal dissipation of the MPS acoustic wave resonators disclosed herein can be advantageous. For example, such thermal dissipation can be desirable in 5G applications with a higher time-division duplexing (TDD) duty cycle compared to fourth generation (4G) Long Term Evolution (LTE). One or more MPS acoustic wave resonators in accordance with any suitable principles and advantages disclosed herein can be included in a filter arranged to filter a radio frequency signal in a 4G LTE operating band and/or in a filter having a passband that includes a 4G LTE operating band and a 5G NR operating band.

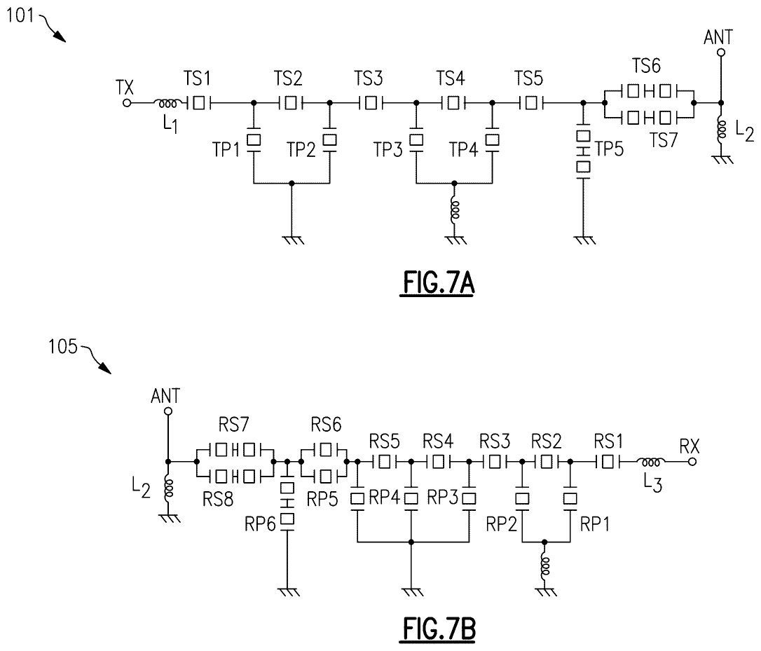

FIG. 7A is a schematic diagram of an example transmit filter 101 that includes surface acoustic wave resonators according to an embodiment. The transmit filter 101 can be a band pass filter. The illustrated transmit filter 101 is arranged to filter a radio frequency signal received at a transmit port TX and provide a filtered output signal to an antenna port ANT. Some or all of the SAW resonators TS1 to TS7 and/or TP1 to TP5 can be a SAW resonator in accordance with any suitable principles and advantages disclosed herein. For instance, one or more of the SAW resonators of the transmit filter 101 can be part of one or more of the packaged acoustic wave components such as the packaged acoustic wave components 100, 100A, 200 of FIGS. 1-5A. Any suitable number of series SAW resonators and shunt SAW resonators can be included in a transmit filter 101.

FIG. 7B is a schematic diagram of a receive filter 105 that includes surface acoustic wave resonators according to an embodiment. The receive filter 105 can be a band pass filter. The illustrated receive filter 105 is arranged to filter a radio frequency signal received at an antenna port ANT and provide a filtered output signal to a receive port RX. Some or all of the SAW resonators RS1 to RS8 and/or RP1 to RP6 can be SAW resonators included in a packaged acoustic wave component in accordance with any suitable principles and advantages disclosed herein. For instance, one or more of the SAW resonators of the receive filter 105 can be part of one or more of the packaged acoustic wave components 100, 100A, 200. Any suitable number of series SAW resonators and shunt SAW resonators can be included in a receive filter 105.

Although FIGS. 7A and 7B illustrate example ladder filter topologies, any suitable filter topology can include a SAW resonator in accordance with any suitable principles and advantages disclosed herein. Example filter topologies include ladder topology, a lattice topology, a hybrid ladder and lattice topology, a multi-mode SAW filter, a multi-mode SAW filter combined with one or more other SAW resonators, and the like.

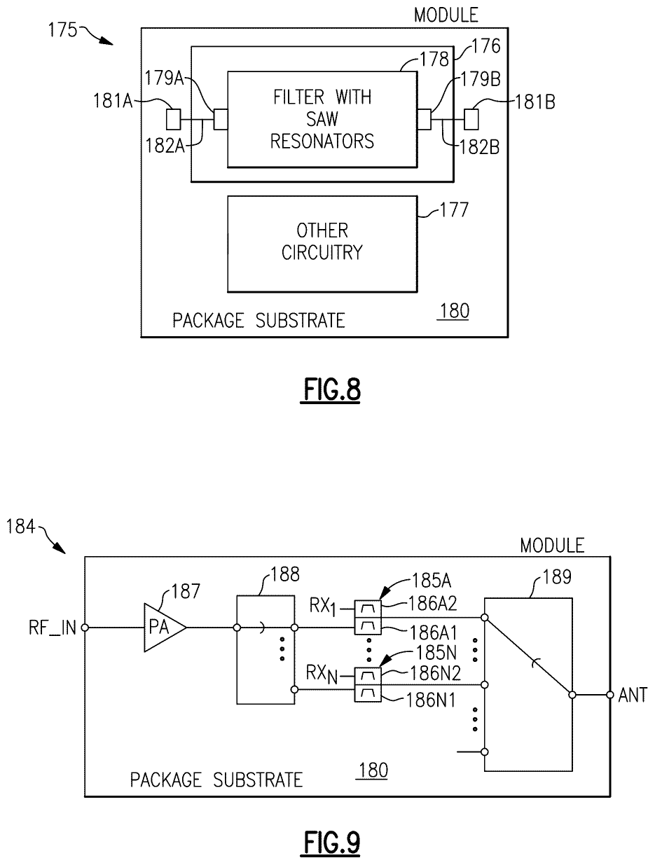

FIG. 8 is a schematic diagram of a radio frequency module 175 that includes a surface acoustic wave component 176 according to an embodiment. The illustrated radio frequency module 175 includes the SAW component 176 and other circuitry 177. The SAW component 176 can include one or more SAW resonators with any suitable combination of features of the SAW resonators or packages disclosed herein. The SAW component 176 can include a SAW die that includes SAW resonators.

The SAW component 176 shown in FIG. 8 includes a filter 178 and terminals 179A and 179B. The filter 178 includes SAW resonators. One or more of the SAW resonators can be implemented in accordance with any suitable principles and advantages of the packaged acoustic wave components 100, 100A, 200. The terminals 179A and 178B can serve, for example, as an input contact and an output contact. The SAW component 176 and the other circuitry 177 are on a common packaging substrate 180 in FIG. 8. The package substrate 180 can be a laminate substrate. The terminals 179A and 179B can be electrically connected to contacts 181A and 181B, respectively, on the packaging substrate 180 by way of electrical connectors 182A and 182B, respectively. The electrical connectors 182A and 182B can be bumps or wire bonds, for example. The other circuitry 177 can include any suitable additional circuitry. For example, the other circuitry can include one or more one or more power amplifiers, one or more radio frequency switches, one or more additional filters, one or more low noise amplifiers, the like, or any suitable combination thereof. The radio frequency module 175 can include one or more packaging structures to, for example, provide protection and/or facilitate easier handling of the radio frequency module 175. Such a packaging structure can include an overmold structure formed over the packaging substrate 180. The overmold structure can encapsulate some or all of the components of the radio frequency module 175.

FIG. 9 is a schematic diagram of a radio frequency module 184 that includes a surface acoustic wave resonator according to an embodiment. As illustrated, the radio frequency module 184 includes duplexers 185A to 185N that include respective transmit filters 186A1 to 186N1 and respective receive filters 186A2 to 186N2, a power amplifier 187, a select switch 188, and an antenna switch 189. In some instances, the module 184 can include one or more low noise amplifiers configured to receive a signal from one or more receive filters of the receive filters 186A2 to 186N2. The radio frequency module 184 can include a package that encloses the illustrated elements. The illustrated elements can be disposed on a common packaging substrate 180. The packaging substrate can be a laminate substrate, for example.

The duplexers 185A to 185N can each include two acoustic wave filters coupled to a common node. The two acoustic wave filters can be a transmit filter and a receive filter. As illustrated, the transmit filter and the receive filter can each be band pass filters arranged to filter a radio frequency signal. One or more of the transmit filters 186A1 to 186N1 can include one or more SAW resonators or packages in accordance with any suitable principles and advantages disclosed herein. Similarly, one or more of the receive filters 186A2 to 186N2 can include one or more SAW resonators in accordance with any suitable principles and advantages disclosed herein. Although FIG. 9 illustrates duplexers, any suitable principles and advantages disclosed herein can be implemented in other multiplexers (e.g., quadplexers, hexaplexers, octoplexers, etc.) and/or in switch-plexers and/or to standalone filters.

The power amplifier 187 can amplify a radio frequency signal. The illustrated switch 188 is a multi-throw radio frequency switch. The switch 188 can electrically couple an output of the power amplifier 187 to a selected transmit filter of the transmit filters 186A1 to 186N1. In some instances, the switch 188 can electrically connect the output of the power amplifier 187 to more than one of the transmit filters 186A1 to 186N1. The antenna switch 189 can selectively couple a signal from one or more of the duplexers 185A to 185N to an antenna port ANT. The duplexers 185A to 185N can be associated with different frequency bands and/or different modes of operation (e.g., different power modes, different signaling modes, etc.).

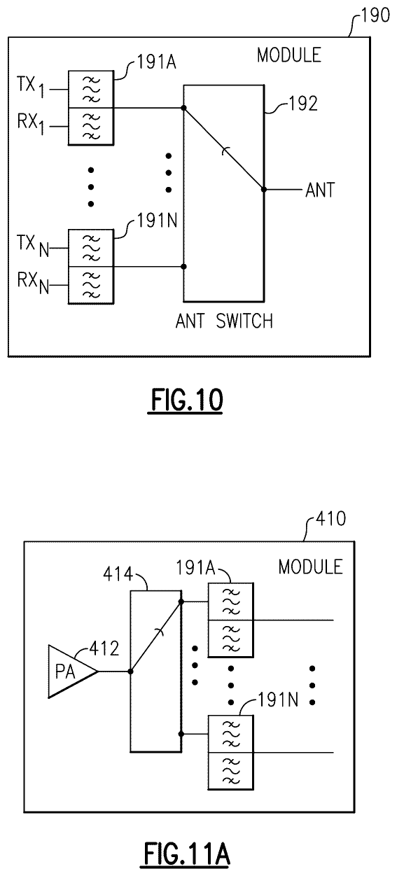

FIG. 10 is a schematic block diagram of a module 190 that includes duplexers 191A to 191N and an antenna switch 192. One or more filters of the duplexers 191A to 191N can include any suitable number of surface acoustic wave resonators or packages in accordance with any suitable principles and advantages discussed herein. Any suitable number of duplexers 191A to 191N can be implemented. The antenna switch 192 can have a number of throws corresponding to the number of duplexers 191A to 191N. The antenna switch 192 can electrically couple a selected duplexer to an antenna port of the module 190.

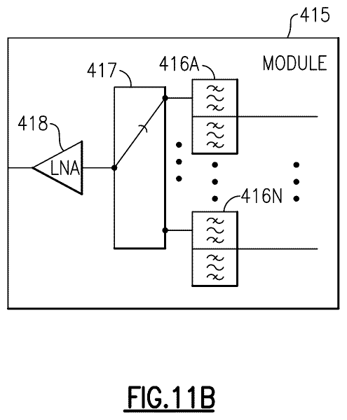

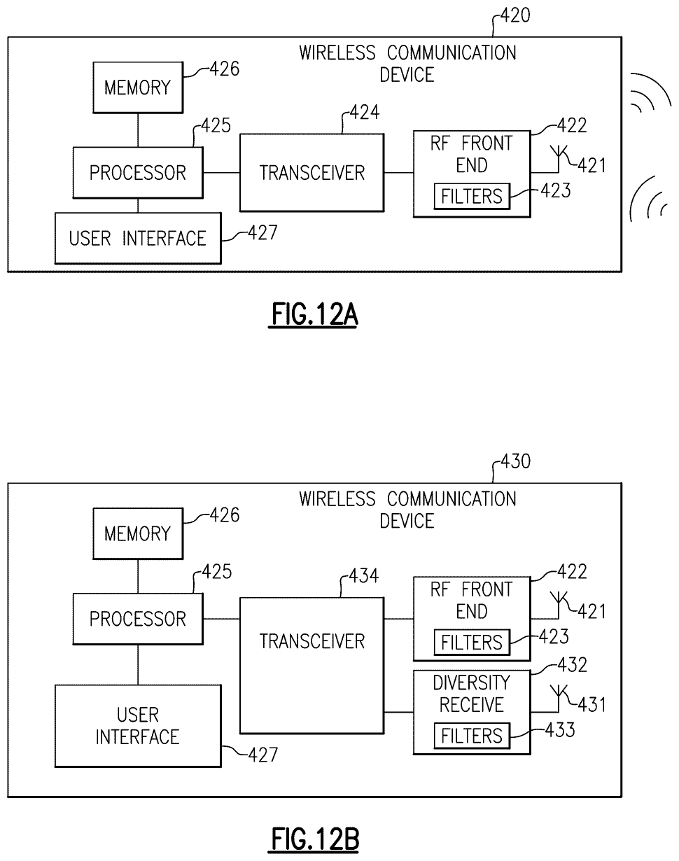

FIG. 11A is a schematic block diagram of a module 410 that includes a power amplifier 412, a radio frequency switch 414, and duplexers 191A to 191N in accordance with one or more embodiments. The power amplifier 412 can amplify a radio frequency signal. The radio frequency switch 414 can be a multi-throw radio frequency switch. The radio frequency switch 414 can electrically couple an output of the power amplifier 412 to a selected transmit filter of the duplexers 191A to 191N. One or more filters of the duplexers 191A to 191N can include any suitable number of surface acoustic wave resonators or packages in accordance with any suitable principles and advantages discussed herein. Any suitable number of duplexers 191A to 191N can be implemented.

FIG. 11B is a schematic block diagram of a module 415 that includes filters 416A to 416N, a radio frequency switch 417, and a low noise amplifier 418 according to an embodiment. One or more filters of the filters 416A to 416N can include any suitable number of acoustic wave resonators or packages in accordance with any suitable principles and advantages disclosed herein. Any suitable number of filters 416A to 416N can be implemented. The illustrated filters 416A to 416N are receive filters. In some embodiments (not illustrated), one or more of the filters 416A to 416N can be included in a multiplexer that also includes a transmit filter. The radio frequency switch 417 can be a multi-throw radio frequency switch. The radio frequency switch 417 can electrically couple an output of a selected filter of filters 416A to 416N to the low noise amplifier 418. In some embodiments (not illustrated), a plurality of low noise amplifiers can be implemented. The module 415 can include diversity receive features in certain applications.

FIG. 12A is a schematic diagram of a wireless communication device 420 that includes filters 423 in a radio frequency front end 422 according to an embodiment. The filters 423 can include one or more SAW resonators or packages in accordance with any suitable principles and advantages discussed herein. The wireless communication device 420 can be any suitable wireless communication device. For instance, a wireless communication device 420 can be a mobile phone, such as a smart phone. As illustrated, the wireless communication device 420 includes an antenna 421, an RF front end 422, a transceiver 424, a processor 425, a memory 426, and a user interface 427. The antenna 421 can transmit/receive RF signals provided by the RF front end 422. Such RF signals can include carrier aggregation signals. Although not illustrated, the wireless communication device 420 can include a microphone and a speaker in certain applications.

The RF front end 422 can include one or more power amplifiers, one or more low noise amplifiers, one or more RF switches, one or more receive filters, one or more transmit filters, one or more duplex filters, one or more multiplexers, one or more frequency multiplexing circuits, the like, or any suitable combination thereof. The RF front end 422 can transmit and receive RF signals associated with any suitable communication standards. The filters 423 can include SAW resonators of a SAW component or package that includes any suitable combination of features discussed with reference to any embodiments discussed above.

The transceiver 424 can provide RF signals to the RF front end 422 for amplification and/or other processing. The transceiver 424 can also process an RF signal provided by a low noise amplifier of the RF front end 422. The transceiver 424 is in communication with the processor 425. The processor 425 can be a baseband processor. The processor 425 can provide any suitable base band processing functions for the wireless communication device 420. The memory 426 can be accessed by the processor 425. The memory 426 can store any suitable data for the wireless communication device 420. The user interface 427 can be any suitable user interface, such as a display with touch screen capabilities.

FIG. 12B is a schematic diagram of a wireless communication device 430 that includes filters 423 in a radio frequency front end 422 and a second filter 433 in a diversity receive module 432. The wireless communication device 430 is like the wireless communication device 420 of FIG. 12A, except that the wireless communication device 430 also includes diversity receive features. As illustrated in FIG. 12B, the wireless communication device 430 includes a diversity antenna 431, a diversity module 432 configured to process signals received by the diversity antenna 431 and including filters 433, and a transceiver 434 in communication with both the radio frequency front end 422 and the diversity receive module 432. The filters 433 can include one or more SAW resonators or packaged acoustic wave components that include any suitable combination of features discussed with reference to any embodiments discussed above.

Although embodiments disclosed herein relate to surface acoustic wave resonators or packages and packaged acoustic wave components, any suitable principles and advantages disclosed herein can be applied to other types of acoustic wave resonators that include an IDT electrode, such as Lamb wave resonators and/or boundary wave resonators. For example, any suitable combination of features of the tilted and rotated IDT electrodes disclosed herein can be applied to a Lamb wave resonator and/or a boundary wave resonator.

Any of the embodiments described above can be implemented in association with mobile devices such as cellular handsets. The principles and advantages of the embodiments can be used for any systems or apparatus, such as any uplink wireless communication device, that could benefit from any of the embodiments described herein. The teachings herein are applicable to a variety of systems. Although this disclosure includes some example embodiments, the teachings described herein can be applied to a variety of structures. Any of the principles and advantages discussed herein can be implemented in association with RF circuits configured to process signals in a frequency range from about 30 kHz to 300 GHz, such as in a frequency range from about 450 MHz to 8.5 GHz. Acoustic wave resonators and/or filters disclosed herein can filter RF signals at frequencies up to and including millimeter wave frequencies.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

Language of degree used herein, such as the terms “approximately,” “about,” “generally,” and “substantially” as used herein represent a value, amount, or characteristic close to the stated value, amount, or characteristic that still performs a desired function or achieves a desired result. For example, the terms “approximately”, “about”, “generally,” and “substantially” may refer to an amount that is within less than 10% of, within less than 5% of, within less than 1% of, within less than 0.1% of, and within less than 0.01% of the stated amount. As another example, in certain embodiments, the terms “generally parallel” and “substantially parallel” refer to a value, amount, or characteristic that departs from exactly parallel by less than or equal to 15 degrees, 10 degrees, 5 degrees, 3 degrees, 1 degree, or 0.1 degree.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A packaged acoustic wave component comprising:
a substrate;
a dielectric layer disposed over the substrate;
a piezoelectric structure disposed over the dielectric layer;
an electrode structure disposed over the piezoelectric structure;
a polymer structure including a polymer structure wall portion and a polymer structure roof portion configured to form a cavity over the electrode structure;
a metal structure disposed over the polymer structure; and
a buffer coating disposed over the metal structure, the buffer coating including a polymer material with a filler material.

2. The packaged acoustic wave component of claim 1 wherein the filler material includes a silica-based filler material.

3. The packaged acoustic wave component of claim 1 wherein the filler material includes one or more of: aluminium oxide, magnesium oxide, borium nitride, and aluminium nitride.

4. The packaged acoustic wave component of claim 1 wherein the polymer material of the buffer coating includes a polyimide material and/or a polybenzoxazole material.

5. The packaged acoustic wave component of claim 1 wherein the buffer coating has a Young's modulus E of 5 gigapascals or more.

6. The packaged acoustic wave component of claim 1 wherein the buffer coating has a coefficient of thermal expansion of 20 ppm or less.

7. The packaged acoustic wave component of claim 1 wherein the buffer coating has a coefficient of thermal expansion of 16.5 ppm or less.

8. The packaged acoustic wave component of claim 1 wherein the polymer structure includes a polymer material, which includes a polyimide material and/or a polybenzoxazole material.

9. The packaged acoustic wave component of claim 1 wherein the polymer structure further includes a filler material.

10. The packaged acoustic wave component of claim 9 wherein the filler material of the polymer structure includes a silica-based filler material.

11. The packaged acoustic wave component of claim 9 wherein the filler material of the polymer structure includes one or more of: aluminium oxide, magnesium oxide, borium nitride, and aluminium nitride.

12. The packaged acoustic wave component of claim 1 wherein the polymer structure has a Young's modulus E of 5 gigapascals or more.

13. The packaged acoustic wave component of claim 1 wherein the polymer structure has a coefficient of thermal expansion of 20 ppm or less.

14. The packaged acoustic wave component of claim 1 wherein the substrate, the dielectric layer and the piezoelectric structure have a common outer lateral edge.

15. The packaged acoustic wave component of claim 1 wherein a gap is arranged between the piezoelectric structure and the polymer structure.

16. The packaged acoustic wave component of claim 15 wherein in the gap the substrate is open to the cavity.

17. The packaged acoustic wave component of claim 1 wherein the electrode structure includes at least one interdigital transducer electrode.

18. A wireless communication device comprising:
a packaged radio frequency device including an acoustic wave component formed from a dielectric layer disposed over a substrate, a piezoelectric structure disposed over the dielectric layer, an electrode structure disposed over the piezoelectric structure, a polymer structure including a polymer structure wall portion and a polymer structure roof portion configured to form a cavity over the electrode structure, a metal structure disposed over the polymer structure, and a buffer coating disposed over the metal structure, the buffer coating including a polymer material with a filler material; and
an antenna coupled to the packaged radio frequency device.

19. The wireless communication device of claim 18 wherein the packaged radio frequency device is a radio frequency front end including the acoustic wave component and a power amplifier.

20. A method of making a packaged acoustic wave component, the method comprising:
forming an acoustic wave device including forming or providing a substrate, forming or providing a piezoelectric structure over at least a portion of the substrate and forming or providing an electrode structure disposed over the piezoelectric structure;
forming or providing a polymer structure including a polymer structure wall portion and a polymer structure roof portion configured to form a cavity over the electrode structure; and
forming or providing a metal structure disposed over the polymer structure; and
forming a buffer coating disposed over the metal structure, the buffer coating including a polymer material with a filler material.
